(19) United States
(12) Patent Application Publication
(10) Pub. No.: US 2005/0083658 A1
(43) Pub. Date: Apr. 21, 2005

(54) Heat dissipating module of an integrated circuit of a portable computer

(75) Inventor: Sung Chuan Huang, Taipei (TW)

Correspondence Address: VOLPE AND KOENIG, P.C., UNITED PLAZA, SUITE 1600, 30 SOUTH 17TH STREET, PHILADELPHIA, PA, 19103, US

(73) Assignee: Arima Computer Corporation, Taipei (TW)

(21) Appl. No.: 10/690,418

(22) Filed: Oct. 21, 2003

(51) Int. Cl. H05K 7/20

(52) U.S. Cl. 361/700

(57) ABSTRACT

A heat-dissipating module of an integrated circuit of a portable computer is provided. It includes a thermal pad, a heatsink, a heatpipe and a phase-transition material. The heatsink has a main portion and an extension portion. A small narrow cross-section area for transferring heat of the heatsink between the main portion and the extension portion is disposed. The heatsink has a round contact surface for solving the problem of poor heat transfer by four strip areas.

### FIELD OF THE INVENTION

The present invention relates to a heat-dissipating module of an integrated circuit of a portable computer, particularly to a heat-dissipating module which utilizes a circular contact surface to substitute a rectangular contact surface and to enhance heat transfer efficiency by using a phase-transition material and a thermal pad.

### BACKGROUND OF THE INVENTION

Please refer to FIG. 1. FIG. 1 is a schematic view showing a heat-dissipating module of prior art. In the drawing, a thermal pad 92 is mounted on an integrated circuit 91 which is mounted on a mother board 95 of a portable computer, such as notebook computer, PDA, tablet computer, etc. A heatsink 93 is put on the thermal pad 92 which is mounted on the integrated circuit 91. Because the contacting surface between the integrated circuit 91 and the heatsink 93 is not even or truly flat, an air gap is generated. The air gap renders poor heat transfer efficiency between the integrated circuit 91 and the heatsink 93. A thermal pad 92 and a thermal compound are inserted between the integrated circuit 91 and the heatsink 93 to increase heat transfer efficiency. For example, the integrated circuit 91 is a CPU made by VIA TECHNOLOGIES, INC. as C3 CPU. When the C3 CPU is put beneath the heatsink 93 and the thermal pad 92, the top surface of VIA C3 CPU will concave downward from the middle point 911 and is deformed after the C3 CPU is put beneath the heatsink 93. After a soft large thermal pad is mounted, the contacting interface between the heatsink 93 and the C3 CPU 91 is four-strip area of rectangular contacting surface. After the top surface of VIA C3 CPU concaves downward and is deformed, the area of contacting surface 931 decreases to one summed by the four strips formed by the edges of the rectangular edge areas 921. Therefore, heat can be transferred by the four strips of the heatsink 93 only and the heat transfer efficiency of the CPU C3 is poor.

From the above, the heat transfer area between the VIA C3 CPU and the heatsink 93 is so small that the poor heat transfer rate of the heatsink will affect the operation temperature and the performance of an integrated circuit seriously. Thus, how to rectify the foresaid conventional drawback is the main purpose of the present invention.

### SUMMARY OF THE INVENTION

It is a object of the present invention to provide a heat dissipating module of an integrated circuit of a portable computer which can solve the above four-strip problem and can attain excellent heat transfer rate.

According to one aspect of the present invention, a heat dissipating module of an integrated circuit of a portable computer comprises:
a thermal pad positioned on said integrated circuit; and
a heatsink fixed on the thermal pad and having a non-rectangular contact surface contacting with the thermal pad so as to dissipate a heat from the integrated circuit.

In accordance with the present invention, a. heat dissipating module of an integrated circuit of a portable computer is provided, wherein preferably the non-rectangular contact surface has a circular shape.

Preferably, the heatsink has a main portion and a extension portion.

Preferably, a phase-transition material is added to the thermal pad and the heatsink.

Preferably, the heat dissipating module further comprises a heatpipe.

Preferably, the heat dissipating module further comprises a fan.

### BRIEF DESCRIPTION OF THE DRAWINGS

FIG. 1 is a side view showing the heat dissipating module according to the prior art;

FIG. 2 is an isometric view illustrating the heat dissipating module according to the present invention;

FIG. 3 is an isometric view illustrating the heatsink of the present invention.

FIG. 4 is a top view showing the heatsink of the present invention;

FIG. 5 is a left side view showing the heatsink of the present invention;

FIG. 6 is a front side view showing the heatsink of the present invention; and

FIG. 7. is a bottom view showing the heatsink of the present invention.

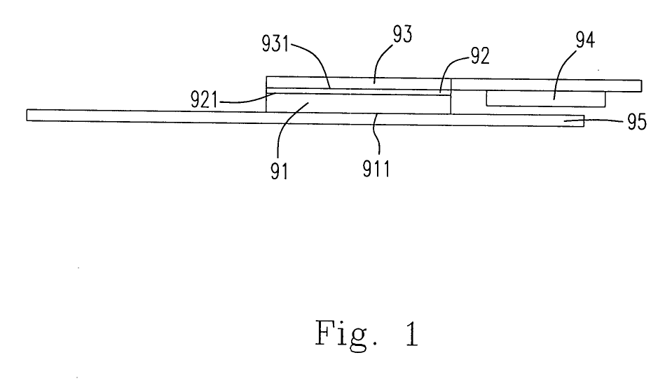

### DETAILED DESCRIPTION OF THE PREFERRED EMBODIMENT

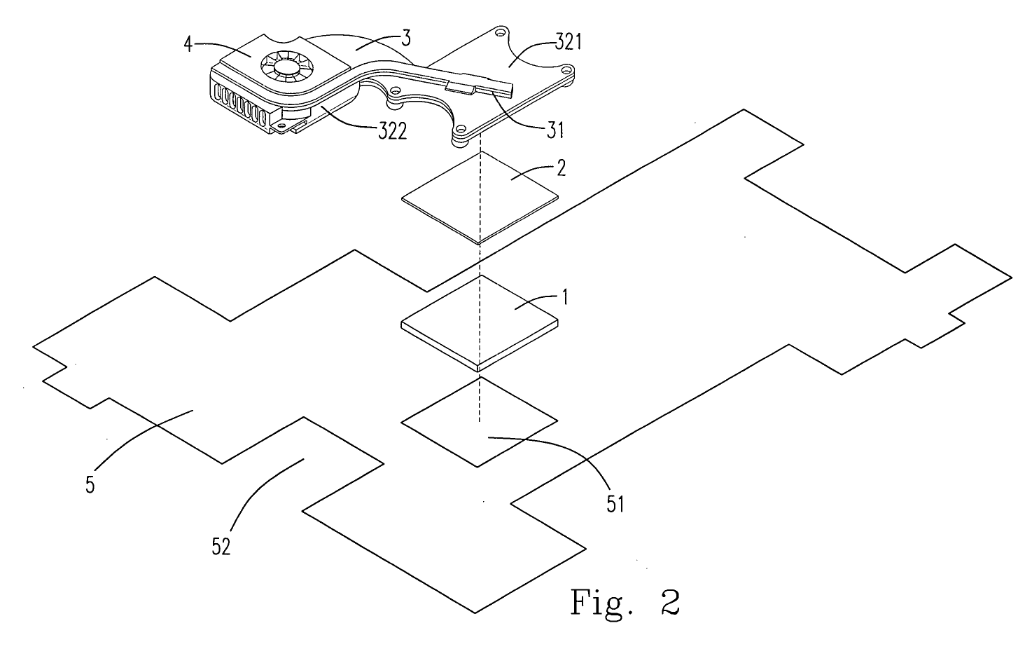

Please refer to FIG. 2 which is an isometric view of the heat-dissipating module of the present invention. In the figure, motherboard 5 has an opening 51 on which a VIA C3 CPU 1 is disposed. A thermal pad 2 is disposed on the C3 CPU 1. The extention portion 321 of the heatsink 3 is put on the thermal pad 2. The main portion 322 of the heatsink 3 is in alignment with the notch 52 on the motherboard 5 after assembling.

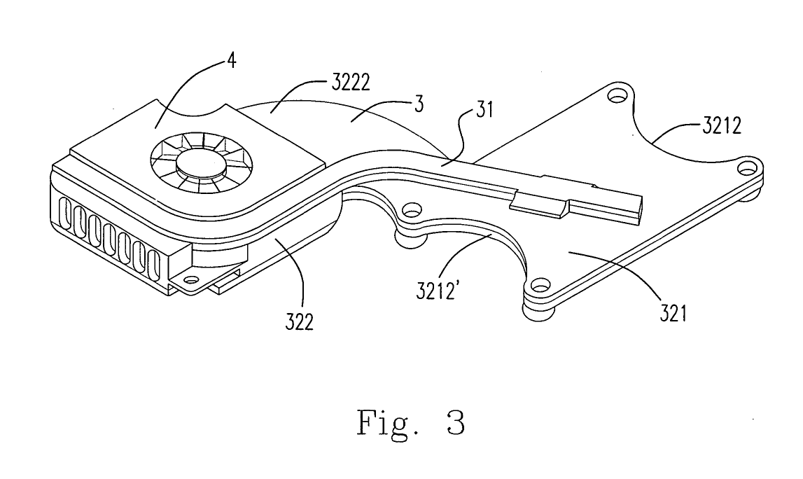

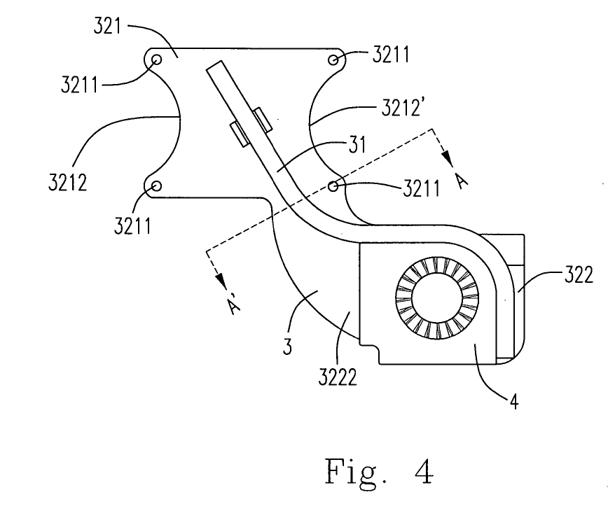

Please refer to FIGS. 3-6. The heatsink 3 which is made of metal alloy having excellent heat transfer rate has the main portion 322 and an extension portion 321 extended from the main portion 322 in order to increase the heat transfer area. Because of the manufacturing process and in order to facilitate mold injection and in order to be adapted to the arrangement of other components in the computer, the heatsink 3 is of the specific shape. In the direction from the main portion 322 to the extension portion 321, a fin portion 3222 is formed. Two arc lines 3212, 3212′ are formed on the extension portion 321. Four fixing holes 3211 are formed on the extension portion 321. The length of the cross-section cut along line A-A′ between the fin portion 3222 and extension portion 321 is about 75% of the width dimension of C3 CPU. Although the cross-section along A-A′ is short and narrow, the effect of heat transfer of the heatsink 3 is very good because heat transfer are mainly achieved by the heatpipe 31.

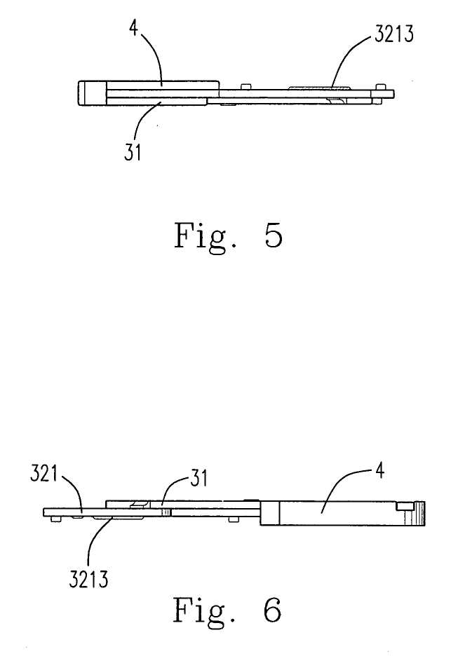

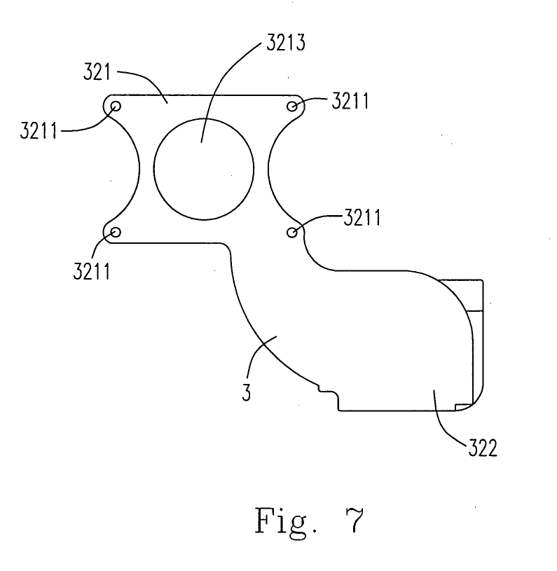

Please refer to FIG. 7 which is a bottom view of the heatsink 3. After FIGS. 5 and 6 are reviewed, heat is transferred from CPU 1 to the main portion 322 of heatsink 3 via a circular contact surface 3213 under the extension portion 321 through the thermal pad 2. Excellent heat transfer is achieved by using the circular contact surface 3213, thermal pad 2 and phase-transition material, the poor heat transfer problem of the four rectangular strips is solved because the circular contact surface 3213 completely contact with the CPU 1.

The shape of the contact surface 3213 is non-rectangular which means that the shape is not rectangular, but not limited to circle. Any kinds of shape which can fulfill the object of the present invention can be used, such as, oval, oblong, polygon. Preferably the shape of the non-rectangular contact surface 3213 has a circular shape.

The thinner the thermal pad 2 is, the better heat transfer rate of the thermal pad 2 is. The materials of thermal pad 2 can be, but not limited to, silver/grey graphite.

The phase-transition material of the present invention is changed from solid phase into liquid phase when the temperature increases from a first temperature to a second temperature so as to adapt the tolerance between extension portion 321 and CPU 1 and to regulate stress.

A fan 4 can be mounted on the main portion 322 in order to drive air through the extension portion 321 as shown in FIG. 2.

As illustrated in FIGS. 2-6, the heatpipe 31 extends from the main portion 322 to the extension portion 321 for efficiently dissipating heat. The species of the heatpipe should not be limited.

The present invention has the following advantages:
1. Because the components of the portable computer are crowded near the mother board and because the C3 CPU concaves after assembling, the C3 CPU still can normally be operated under a temperature of about 75° C. by using the heat dissipating module of the present invention.
2. Although the heatsink has a narrow small cross-section, a good heat transfer is also achieved.
3. The heat-dissipating module of the present invention can be used in very thin notebook computer.

While the invention has been described in terms of what is presently considered to be the most practical and preferred embodiments, it is to be understood that the invention needs not be limited to the disclosed embodiments. On the contrary, it is intended to cover various modifications and similar arrangements included within the spirit and scope of the appended claims which are to be accorded with the broadest interpretation so as to encompass all such modifications and similar structures.

1. A heat-dissipating module of an integrated circuit of a portable computer comprising:
a thermal pad positioned on said integrated circuit; and
a heatsink fixed to said thermal pad and having a non-rectangular contact surface contacting with said thermal pad so as to dissipate a heat produced from said integrated circuit.

2. The heat-dissipating module of an integrated circuit of a portable computer according to claim 1, wherein said non-rectangular contact surface has a circular shape.

3. The heat-dissipating module of an integrated circuit of a portable computer according to claim 1, wherein said heatsink has a main portion and an extension portion.

4. The heat-dissipating module of an integrated circuit of a portable computer according to claim 1, wherein a phase-transition material is added to said thermal pad and said heatsink.

5. The heat dissipating module of an integrated circuit of a portable computer according to claim 1, wherein said heat dissipating module further comprises a heatpipe.

6. The heat dissipating module of an integrated circuit of a portable computer according to claim 1, wherein said heat dissipating module further comprises a fan.
